(19) United States
(12) Patent Application Publication
(10) Pub. No.: US 2022/0328714 A1
(43) Pub. Date: Oct. 13, 2022

(54) SOLAR CELL GROUP MANUFACTURING DEVICE, SOLAR CELL GROUP, AND METHOD FOR MANUFACTURING SOLAR CELL GROUP

(71) Applicant: KANEKA CORPORATION, Osaka (JP)

(72) Inventor: Gensuke KOIZUMI, Osaka (JP)

(73) Assignee: KANEKA CORPORATION, Osaka (JP)

(21) Appl. No.: 17/753,351

(22) PCT Filed: Jun. 15, 2020
(86) PCT No.: PCT/JP2020/023379

§ 371 Date: Feb. 28, 2022

(30) Foreign Application Priority Data
Sep. 10, 2019 (JP) 2019-164480
Sep. 10, 2019 (JP) 2019-164481
Sep. 10, 2019 (JP) 2019-164482

(51) Int. Cl. H01L 31/18; H01L 31/042

(52) U.S. Cl. CPC H01L 31/1876; H01L 31/042

(57) ABSTRACT

An object of the present invention is to provide a manufacturing apparatus for a solar cell group that is likely to be recognized as having a good color balance when viewed by humans. The manufacturing apparatus for a solar cell group of the present invention includes an arrangement operation unit (12) that arranges solar cells and a machine learning unit (20). The solar cell group is formed by planarly arranging the solar cells. The solar cells have a light receiving surface and include an antireflection material on the light receiving surface side. Some of the solar cells have a variation in color element due to a difference in thickness of the antireflection material or a difference in refractive index of the antireflection material. The machine learning unit (20) performs machine learning using a correlation between an arrangement of the solar cells and a determination result by humans on color balance of the solar cell group as training data. When the solar cell group is manufactured, the machine learning unit (20) generates an arrangement model of the solar cells that is predicted to be determined to have a good color balance as the solar cell group by humans' visual recognition based on information on color elements of each solar cell, and then the arrangement operation unit (12) arranges each of the solar cells based on the arrangement model.

### TECHNICAL FIELD

The present invention relates to a manufacturing apparatus for a solar cell group, a solar cell group, and a method for manufacturing a solar cell group.

### BACKGROUND ART

A so-called back type contact solar cell in which an electrode is provided only on the back surface side and no electrode is provided on the light receiving surface side has been known conventionally (for example, Patent Document 1).

The back contact type solar cell, whose electrodes gather on the back surface, can enlarge the light receiving surface of the solar cell, and can take in more light.

A solar cell module using the back contact type solar cell, whose wiring member connecting the solar cells is also provided on the back surface side, can give a viewer an impression that the appearance is uniform in a room or the like.

The back contact type solar cell is provided with an antireflection film on the light receiving surface side in order to trap received light in the solar cell, and the antireflection film substantially determines the apparent color elements.

### PRIOR ART DOCUMENT

### Patent Document

Patent Document 1: JP 2018-170482 A

### DISCLOSURE OF INVENTION

### Technical Problem

Usually, when solar cells are mass-produced, a large number of solar cells are simultaneously provided with an antireflection film on the light receiving surface under the same conditions. However, even when the antireflection film is formed under the same conditions in each solar cell, the thickness of the antireflection film may be slightly different or the refractive index of the antireflection film may be different between the solar cells due to the influence of the film formation position, heating temperature, and the like when the antireflection film is produced, and there is an individual difference.

In such a case, when the solar cells are randomly arranged and connected by a wiring member to form a module, color unevenness may be recognized when sunlight is applied as shown in FIG. 15B although it is hardly recognized in a room or the like with low illuminance as shown in FIG. 15A. Therefore, the conventional solar cell module has a problem of color unevenness between the solar cells, a bad color balance, and lacking of uniformity in color element when viewed under sunlight.

In some cases, the solar cell module forms a wall surface using a plurality of solar cell modules. In such a case as well, when the solar cell modules are different in color balance, the wall surface formed has a problem of having a bad color balance of the entire wall surface and lacking uniformity in color element.

An object of the present invention is to provide a manufacturing apparatus for a solar cell group that is likely to be recognized as having a good color balance when viewed from human eyes under sunlight.

An object of the present invention is to provide a solar cell group and a method for manufacturing a solar cell group that is likely to be recognized as having a good color balance when viewed from human eyes under sunlight.

### Solution to Problem

In view of the above problem, the inventor of the present invention has considered as follows.

The above problem seems to be solved by simply using only the solar cells having close color elements side by side to improve the color balance. However, when only the solar cells having close color elements are simply used, unusable solar cells with no abnormality in performance are generated, which leads to a problem of decrease in yield. Therefore, to maintain the yield, it is preferable to manufacture a solar cell module using as many solar cells as possible.

A human brain recognizes a motion by recognizing an image recognized by eyes as a still image and connecting the still images. Therefore, a human has a trick of the eye (optical illusion), recognizing a uniform color as non-uniform colors or recognizing a non-uniform color distribution as a uniform color distribution.

Accordingly, the inventor has considered using more solar cells by using this illusion of human eyes.

However, although there is a tendency in the illusion of human eyes, the principle of the illusion is often not found from a scientific point of view, and there is no choice but to consider the arrangement based on what is actually determined by humans. Therefore, it is difficult to artificially derive a combination in which an optical illusion occurs and the color balance is seen as good from an enormous combination of solar cells.

Accordingly, the inventor has considered incorporating a machine learning program into a manufacturing apparatus and causing the manufacturing apparatus to learn the color and arrangement of solar cells and a determination by humans on color balance through machine learning, to cause the manufacturing apparatus itself to derive an arrangement that makes humans feel that the color balance is good.

One aspect of the present invention derived based on the above idea is an manufacturing apparatus for a solar cell group, including: an arrangement operation unit that arranges a plurality of solar cells constituting the solar cell group; and a machine learning unit, wherein the solar cell group includes a plurality of solar cells arranged planarly, wherein the plurality of solar cells each include: a light receiving surface; and an antireflection material on a light receiving surface side, wherein the plurality of solar cells include a first solar cell having a variation in a color element due to a difference in thickness of the antireflection material or a difference in refractive index of the antireflection material, wherein the machine learning unit performs machine learning using a correlation between an arrangement of the plurality of solar cells and a determination result by humans on color balance of the solar cell group under the arrangement as training data, wherein when the solar cell group is manufactured, the machine learning unit generates an arrangement model of the solar cells, the arrangement model being predicted to be determined to have a good color balance as the solar cell group by humans' visual recognition based on information on color elements of each of the solar cells, and wherein the arrangement operation unit arranges each of the solar cells based on the arrangement model.

The term “color balance” as used herein includes not only homogeneity but also color balance of a design or a pattern when solar cells form a design or a pattern.

The term “good” as used herein means normal or better than normal. For example, a middle or higher evaluation when the evaluation is made in a multi-grade evaluation is referred to as “good”.

The solar cells in this aspect are formed through the same manufacturing process. However, a disarray in color element occurs between the solar cells due to a difference in thickness of the antireflection material or in refractive index of the antireflection material.

According to this aspect, the machine learning unit performs machine learning for a subjective determination on color balance by humans, and the machine learning unit generates, in consideration of the slight disarray in color element, an arrangement model that is predicted to be determined as having a good color balance in the solar cell group by humans. Therefore, it is possible to set an arrangement in consideration of the illusion of human eyes, and more solar cells can be used for manufacturing the solar cell group regardless of the color variation. Therefore, it is possible to improve the yield as compared with the case of simply arranging solar cells having similar color distributions.

In addition, according to this aspect, it is possible to make a determination on color balance close to human sensitivity in the manufacturing apparatus, which enables automation of the arrangement of the solar cells.

In a preferred aspect, the solar cell group is a solar cell module that includes the plurality of solar cells electrically connected by a wiring member, and each of the solar cells is connected by the wiring member on a side opposite to the light receiving surface.

In a preferred aspect, the solar cell is a solar cell module including the plurality of solar cells sandwiched between two sealing members, and the sealing member on the light receiving surface side has translucency, the antireflection material being interposed between the sealing member and the solar cells.

Under sunlight with high illuminance, variations in brightness are more likely to be noticeable than variations in chromaticity.

Therefore, in a preferred aspect, the plurality of solar cells include a second solar cell having variation in brightness due to the difference in thickness of the antireflection material or the difference in refractive index of the antireflection material, the machine learning unit performs machine learning using a correlation between the arrangement of the plurality of solar cells and a determination result by humans on the variation in brightness of the solar cell group under the arrangement, as training data, and wherein when the solar cell group is manufactured, the machine learning unit generates an arrangement model of the solar cells, the arrangement model being predicted to be determined to have a small variation in brightness of the plurality of solar cells in the solar cell group by humans' visual recognition based on information on brightness of each solar cell.

In a preferred aspect, the apparatus acquires a distribution of color elements of 500 or more solar cells and extracting a predetermined number of the solar cells from the 500 or more solar cells such that the distribution of the color elements is substantially maintained, and the machine learning unit performs machine learning using a correlation between an arrangement of the predetermined number of solar cells and a determination result by humans on color balance under the arrangement, as training data.

The phrase “a predetermined number of solar cells are extracted such that the distribution of color elements is substantially maintained” as used herein means that the tendency of the color distribution coincides with the tendency of the distribution of color elements of the population when the color distribution of a predetermined number of solar cells as a sample is acquired.

In a preferred aspect, the machine learning unit is capable of predicting a determination result on the color balance of the solar cell group when viewed by humans based on information on color elements and arrangement of each of the solar cells, the apparatus includes a second machine learning unit, the second machine learning unit replaces the arrangement of the plurality of solar cells in the solar cell group to provide the machine learning unit with the information on color elements and arrangement of each of the solar cells when replaced, thereafter making the machine learning unit perform machine learning to determine the color balance of the solar cell group, then performing machine learning using a correlation between the arrangement of the plurality of solar cells and a determination result by the machine learning unit as training data, when the solar cell group is manufactured, the second machine learning unit generates a second arrangement model of the solar cells, the second arrangement model being predicted to be determined to have a color balance of the solar cell group better than that by the machine learning unit, and when the second machine learning unit generates the second arrangement model, the arrangement operation unit arranges each of the solar cells based on the second arrangement model.

An aspect of the present invention is a manufacturing apparatus for a solar cell group, including an arrangement operation unit that arranges a plurality of solar cells constituting a solar cell group, a machine learning unit, and a second machine learning unit, wherein the solar cell group is formed by planarly arranging the plurality of solar cells, wherein the plurality of solar cells have a light receiving surface and include an antireflection material on the light receiving surface side, and wherein some of the plurality of solar cells have a variation in color element due to a difference in thickness of the antireflection material or a difference in refractive index of the antireflection material. The machine learning unit performs machine learning in advance, using a correlation between color elements and an arrangement of the plurality of solar cells, and a result of determination by humans on color balance of the solar cell group, as training data, and is capable of predicting a result of determination on the color balance of the solar cell group when viewed by humans based on information of color elements and arrangement of each of the solar cells. The second machine learning unit replaces the arrangement of the plurality of solar cells in the solar cell group, gives the machine learning unit the information of color elements and arrangement of each of the solar cells replaced to cause the machine learning unit to perform a determination on the color balance of the solar cell group, and performs machine learning using a correlation between the arrangement of the plurality of solar cells and a result of determination by the machine learning unit as training data When the solar cell group is manufactured, the second machine learning unit generates an arrangement model of the solar cells that is predicted to be determined as having a color balance of the solar cell group better than that by the machine learning unit, and the arrangement operation unit arranges each of the solar cells based on the arrangement model.

The solar cells in this aspect are formed through the same manufacturing process. However, a disarray in color element occurs between the solar cells due to a difference in thickness of the antireflection material or in refractive index of the antireflection material. The machine learning unit according to the present aspect performs machine learning in advance using a correlation between the color elements and arrangement of the solar cells, and a result of determination by humans on the color balance of the solar cell group, as training data, and has a determination criterion close to human subjective view.

According to this aspect, the second machine learning unit performs machine learning based on the determination by the machine learning unit on color balance close to human subjective view, and the second machine learning unit generates an arrangement model that is predicted to be determined as having a good color balance in the solar cell group by humans. Therefore, it is possible to set an arrangement in consideration of the illusion of human eyes, and more solar cells can be used for manufacturing the solar cell group. Therefore, it is possible to improve the yield as compared with the case of simply arranging solar cells having similar color distributions.

In addition, according to this aspect, it is possible to make a determination on color balance close to human sensitivity in the manufacturing apparatus, which enables automation of the arrangement of the solar cells.

Furthermore, according to the present aspect, the machine learning unit gives the training data to the second machine learning unit, and therefore it is possible to give the training data to the second machine learning unit without a determination by humans.

An aspect of the present invention is a machine learning program that gives an arrangement operation unit that arranges a plurality of solar cells constituting a solar cell group based on an arrangement model, wherein the solar cell group is formed by planarly arranging the plurality of solar cells, the plurality of solar cells have a light receiving surface and include an antireflection material on the light receiving surface side, some of the plurality of solar cells have a variation in color element due to a difference in thickness of the antireflection material or a difference in refractive index of the antireflection material, the machine learning unit performs machine learning using a correlation between an arrangement of the plurality of solar cells and a result of determination by humans on color balance of the solar cell group in the arrangement of the plurality of solar cells, as training data, and the machine learning unit generates an arrangement model of the solar cells that is predicted to be determined as having a good color balance in the solar cell group when viewed by humans based on information of color elements of each solar cell.

The solar cells in this aspect are formed through the same manufacturing process. However, a disarray in color element occurs between the solar cells due to a difference in thickness of the antireflection material or in refractive index of the antireflection material.

According to this aspect, the machine learning unit performs a subjective determination on color balance by humans, and the machine learning unit generates, in consideration of the slight disarray in color element, an arrangement model that is predicted to be determined as having a good color balance in the solar cell group by humans. Therefore, it is possible to set an arrangement in consideration of the illusion of human eyes.

One aspect of the present invention is a solar cell group including 20 or more solar cells planarly arranged in total, wherein each of the solar cells includes a light receiving surface and an antireflection material on a light receiving surface side, wherein the plurality of solar cells include a first solar cell having a variation in color element due to a difference in thickness of the antireflection material or a difference in refractive index of the antireflection material, and wherein the solar cell group satisfies the following condition (1) or (2) in CIE 1976 (L*, a*, b*) color system calculated from an image obtained by photographing the solar cells under irradiation of direct sunlight:

(1) a difference between a maximum value and a minimum value of brightness L* of each solar cell is 2.0 or more, and a difference in brightness L* between adjacent solar cells is 1.5 or less;

(2) a difference between a maximum value and a minimum value of chromaticity b* of each solar cell is 4.0 or more, and a difference in chromaticity b* between adjacent solar cells is 1.5 or less.

The solar cell group of this aspect has a large absolute value of the color element of at least one of the brightness L* and the chromaticity b* of each solar cell and has a variety in color element of the entire solar cells. That is, when the solar cells are simply arranged, there is no uniformity in color element, and color unevenness occurs.

According to this aspect, the difference in color element of at least one of the brightness L* and the chromaticity b* of the adjacent solar cells is small even with a variation in color element of the entire solar cells, and therefore the solar cell group is coherent and has homogeneity as a whole and uniformity in color element.

In a preferred aspect, the solar cells includes a second solar cell disposed adjacent to at least three of the solar cells, and the solar cell group satisfies the following condition (3) or (4) in the CIE 1976 (L*, a*, b*) color system calculated from an image obtained by photographing the solar cells under irradiation of direct sunlight:

(3) the condition (1) is satisfied, and a difference in the brightness L* between the second solar cell and the three of the solar cells is 1.8 or less;

(4) the condition (2) is satisfied, and a difference in the chromaticity b* between the second solar cell and the three of the solar cells is 2.0 or less.

In a preferred aspect, each of the brightness L* and the chromaticity b* of each of the solar cells is an average value measured at a plurality of measurement points in the solar cell.

In a preferred aspect, the solar cells are arranged in a grid pattern, and a shortest distance between adjacent solar cells is 5 mm or less.

According to this aspect, the interval between adjacent solar cells is as narrow as 5 mm or less, and therefore the color balance further improves.

In a preferred aspect, the solar cell is a solar cell module including the plurality of solar cells sandwiched between two sealing members, and the sealing member on the light receiving surface side has translucency, the antireflection material being interposed between the sealing member and the solar cell.

An aspect of the present invention is a method for manufacturing a solar cell group including a plurality of solar cells arranged planarly, the method including the steps of: a) forming the solar cells; b) measuring color elements of the solar cells; c) transmitting a measurement result in step b) to an arrangement determination device; d) determining an arrangement of the solar cells constituting the solar cell group based on the measurement result received by the arrangement determination device; and e) arranging the solar cells based on a determination of the arrangement determination device in step d).

According to this aspect, the arrangement of the solar cells is determined using the measurement result in step b), and therefore a solar cell group having a good color balance based on the measurement result of color elements can be manufactured.

In a preferred aspect, step d) determines the arrangement of the solar cells in consideration of the measurement result such that each solar cell has a good color balance, the arrangement being determined based on past measurement results in color elements of each of the solar cells in the solar cell group and past determination results whether to have a good color balance between each of the solar cells in the solar cell group.

In a preferred aspect, the solar cell includes an identification part, the method includes: f) associating the identification part of the solar cell with the measurement result; and g) accommodating the solar cell associated with the measurement result in step f) into an accommodating member, and in step e), the solar cell associated with the measurement result in step f) is taken out from the accommodating member and is arranged based on the determination result of the arrangement determination device in step d).

In a preferred aspect, step b) measures the color elements of the solar cell at a plurality of measurement points, and step d) determines the arrangement of the solar cells using an average value of the color elements measured at the plurality of measurement points.

### Effect of Invention

According to the manufacturing apparatus for a solar cell group of the present invention, even when the solar cell group is viewed under sunlight, it is likely to be recognized as having a good color balance.

According to the solar cell group and the method for manufacturing a solar cell group of the present invention, even when the solar cell group is viewed under sunlight, it is likely to be recognized as having a good uniformity in color element.

### BRIEF DESCRIPTION OF DRAWINGS

FIG. 1 is a block diagram of a module manufacturing apparatus according to a first embodiment of the present invention.

FIGS. 2A and 2B are explanatory diagrams schematically showing a solar cell module that can be manufactured by the module manufacturing apparatus of FIG. 1, wherein

FIG. 2A is a perspective view as viewed from a front surface side, and FIG. 2B is a perspective view as viewed from the back surface side.

FIG. 3 is an exploded perspective view of the solar cell module in FIG. 2B.

FIG. 4 is a perspective view of a main portion of the solar cell module in FIG. 3.

FIG. 5 is a cross-sectional view of the solar cell module in FIG. 2B.

FIGS. 6A and 6B are explanatory diagrams of a deep learning unit in FIG. 1, wherein FIG. 6A is a schematic view showing a neuron model, and FIG. 6B is a schematic view showing a neural network model.

FIGS. 7A and 7B are explanatory diagrams showing a relationship between population solar cells and sample solar cells manufactured by a manufacturing unit in FIG. 1, wherein FIG. 7A is a graph of the number of the population solar cells to the brightness, and FIG. 7B is a graph of the number of the sample solar cells to the brightness.

FIGS. 8A and 8B are images simulating solar cells of a solar cell module manufactured by the manufacturing unit in FIG. 1, wherein FIG. 8A shows a case of low illuminance light irradiation and FIG. 8B shows a case of pseudo sunlight irradiation.

FIG. 9 is a block diagram of a wall surface manufacturing apparatus according to a second embodiment of the present invention.

FIG. 10 is a perspective view schematically showing a wall surface structure that can be manufactured by the wall surface manufacturing apparatus in FIG. 9.

FIG. 11 is a perspective view of the wall surface structure in FIG. 10 as viewed from another direction.

FIG. 12 is a cross-sectional view of the solar cell module in FIG. 11.

FIG. 13 is a block diagram of a module manufacturing apparatus according to a third embodiment of the present invention.

FIG. 14 is a cross-sectional view of a solar cell module manufactured by a manufacturing apparatus according to another embodiment of the present invention.

FIGS. 15A and 15B are images simulating solar cells of a conventional solar cell module, wherein FIG. 15A shows a case of low illuminance light irradiation and FIG. 15B shows a case of pseudo sunlight irradiation.

### BEST MODE FOR CARRYING OUT THE INVENTION

Hereinafter, a module manufacturing apparatus 1 according to a first embodiment of the present invention will be described in detail.

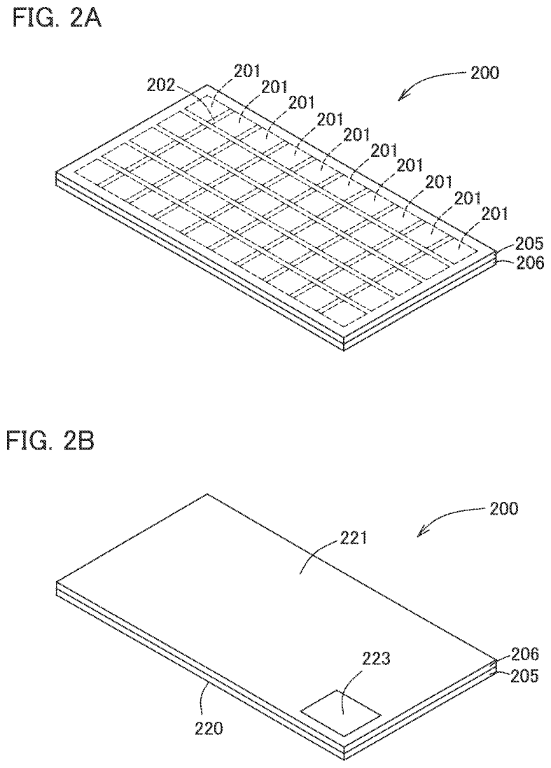

The module manufacturing apparatus 1 of the first embodiment of the present invention manufactures a solar cell module 200 (solar cell group) incorporating a plurality of solar cells 201 shown in FIG. 2.

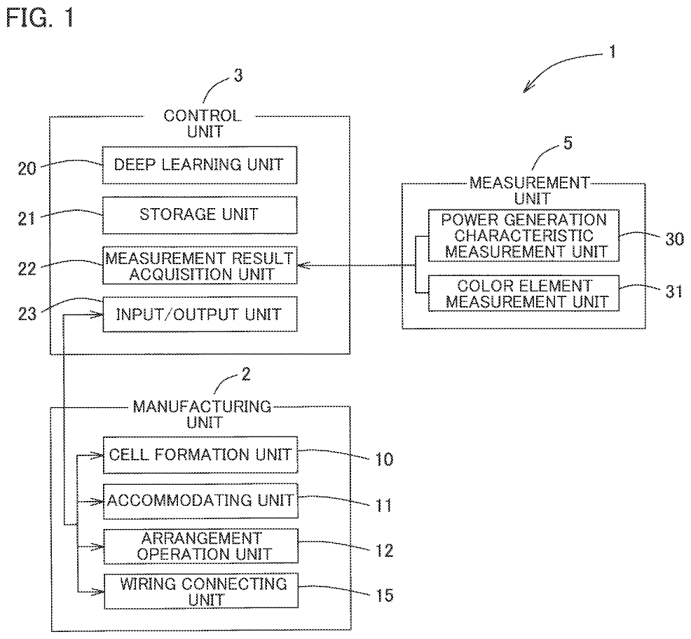

As shown in FIG. 1, the module manufacturing apparatus 1 includes a manufacturing unit 2, a control unit 3, and a measurement unit 5.

The module manufacturing apparatus 1 is provided with a deep learning unit 20 that is operated by a machine learning program in the control unit 3, and an arrangement model of the solar cells 201 is generated based on a result of machine learning performed in advance by the deep learning unit 20. One of the features of the module manufacturing apparatus 1 is that the solar cells 201 are arranged and manufactured based on the generated arrangement model.

As shown in FIG. 1, the manufacturing unit 2 includes a cell formation unit 10, an accommodating unit 11, an arrangement operation unit 12, and a wiring connecting unit 15 as main components. In addition, various devices such as a sealing portion for sealing the solar cells 201 are provided, but the devices are similar to the conventional devices, and thus the description thereof is omitted.

The cell formation unit 10 is a part for forming the solar cells 201, and includes a plurality of film forming devices such as a CVD device.

The accommodating unit 11 is an accommodating member that temporarily accommodates the solar cells 201 measured by the measurement unit 5. The accommodating unit 11 is provided with a plurality of rooms capable of accommodating the solar cells 201.

The arrangement operation unit 12 is a portion for taking out and arranging a predetermined solar cell 201 from the accommodating unit 11 based on the arrangement model formed by the deep learning unit 20 of the control unit 3. The solar cells 201 formed by the cell formation unit 10 may be directly arranged.

The wiring connecting unit 15 is a part that connects a wiring member 202 between the solar cells 201, 201 arranged in a predetermined arrangement by the arrangement operation unit 12.

The control unit 3 is constituted with an arithmetic device, a control device, a storage device, and an input/output device, and includes the deep learning unit 20 (machine learning unit, arrangement determination device), a storage unit 21, a measurement result acquisition unit 22, and an input/output unit 23 as main components as shown in FIG. 1.

The control unit 3 may be provided in a building different from the building where the manufacturing unit 2 and the measurement unit 5 are provided. In this case, the control unit 3 is preferably communicably interconnected to the manufacturing unit 2 and the measurement unit 5 via a network such as an intranet. The control unit 3 may be connected to the manufacturing unit 2 and the measurement unit 5 via the Internet or the like. This allows the manufacturing unit 2 and the measurement unit 5 to be collectively managed at a plurality of bases of different buildings.

The deep learning unit 20 is a machine learning unit operable based on a machine learning program.

The deep learning unit 20 has a function of performing machine learning, by itself, using the color elements and arrangement of each solar cell 201 as well as a result of determination by humans on the color balance of the solar cell module 200 as training data. Based on the result of the machine learning, the deep learning unit 20 can create an arrangement model of the solar cells 201 that is expected to be determined as having a good color balance by humans based on the color elements of each solar cell 201 acquired by the measurement result acquisition unit 22.

The deep learning unit 20 can perform supervised learning in accordance with an algorithm such as a neural network described later.

Here, “supervised learning” is that the deep learning unit 20 is given a large amount of training data, that is, data sets of a certain input and result, learns features in the data sets, and inductively acquires a model (error model) of estimating the result from the input, that is, a relationship between the input and the result.

The deep learning unit 20 of the present embodiment associates the color elements of each solar cell 201, the arrangement of each solar cell 201 in the solar cell module 200, and the result of determination by humans on the color balance of the solar cell module 200 with the arrangement, and performs machine learning for the correlation between the color elements of each solar cell 201 and the arrangement of each solar cell 201, and the result on how humans determine the quality. Then, the deep learning unit 20 can generate, based on a result of machine learning, an arrangement model that is expected to be determined as good by humans based on information on the color elements of each solar cell 201. The deep learning unit 20 of the present embodiment can further predict a result of determination on the color balance of the solar cell module 200 when viewed by humans based on the information on the color elements of each solar cell 201.

Details of the deep learning unit 20 of the present embodiment will be described later.

The storage unit 21 includes a storage device such as a memory or a hard disk, and is a data accumulation unit that stores and accumulates data used in machine learning performed by the deep learning unit 20, past and current manufacturing parameters used for manufacturing the solar cells 201 in the manufacturing unit 2, various measurement parameters such as power generation characteristics and the color elements of each solar cell 201 measured by the measurement unit 5, the arrangement model generated by the deep learning unit 20, and the like.

The measurement result acquisition unit 22 is a part that acquires the measurement results of the power generation characteristics, the color elements, and the like measured by the measurement unit 5 and transmits the measurement results to the storage unit 21 and/or the deep learning unit 20.

The input/output unit 23 is a part that inputs and outputs data to and from the manufacturing unit 2, and is a part that outputs the arrangement model generated by the deep learning unit 20 to the arrangement operation unit 12 of the manufacturing unit 2.

The measurement unit 5 is a part that measures the characteristics of the solar cells 201 formed by the cell formation unit 10 of the manufacturing unit 2, and includes a power generation characteristic measurement unit 30 and a color element measurement unit 31. The power generation characteristic measurement unit 30 is a part that measures the power generation characteristics of the solar cells 201.

The color element measurement unit 31 is a part that measures the color elements of the solar cells 201.

Next, the solar cell module 200 to be manufactured will be described.

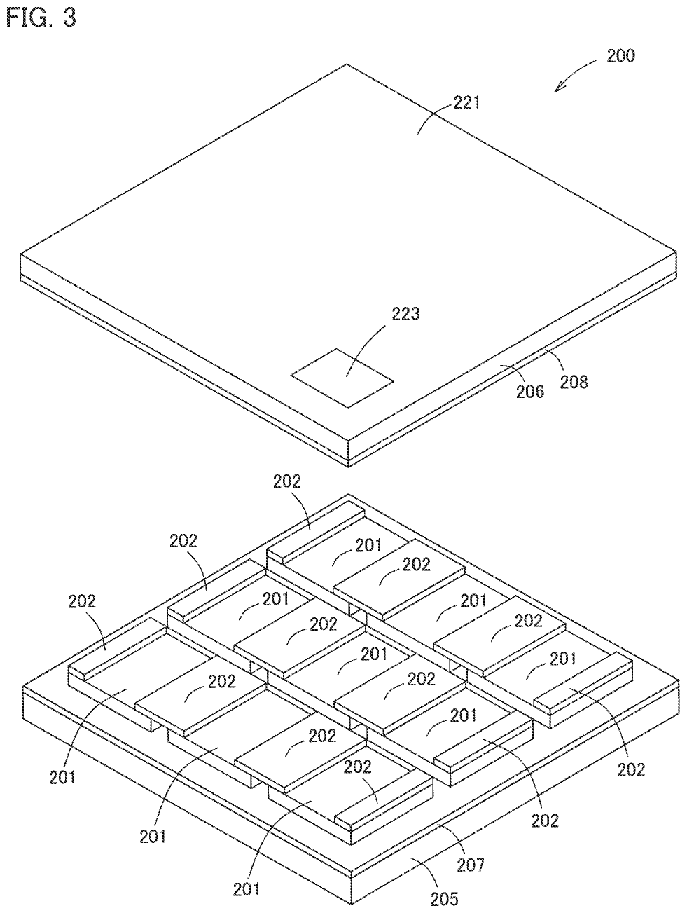

As shown in FIGS. 2 and 3, in the solar cell module 200, a plurality of solar cells 201 electrically connected by the wiring member 202 is arranged between two sealing substrates 205, 206, and a space between the sealing substrates 205, 206 is filled with a sealing material 207, 208.

The solar cell module 200 has a plate shape, in which the solar cells 201 are planarly arranged based on the above-described arrangement model, and the wiring member 202 is provided only on the back surface side of the solar cells 201.

As shown in FIG. 2A, the solar cell module 200 of the present embodiment incorporates 20 or more solar cells 201 in total, and the solar cells 201 are arranged in a grid pattern.

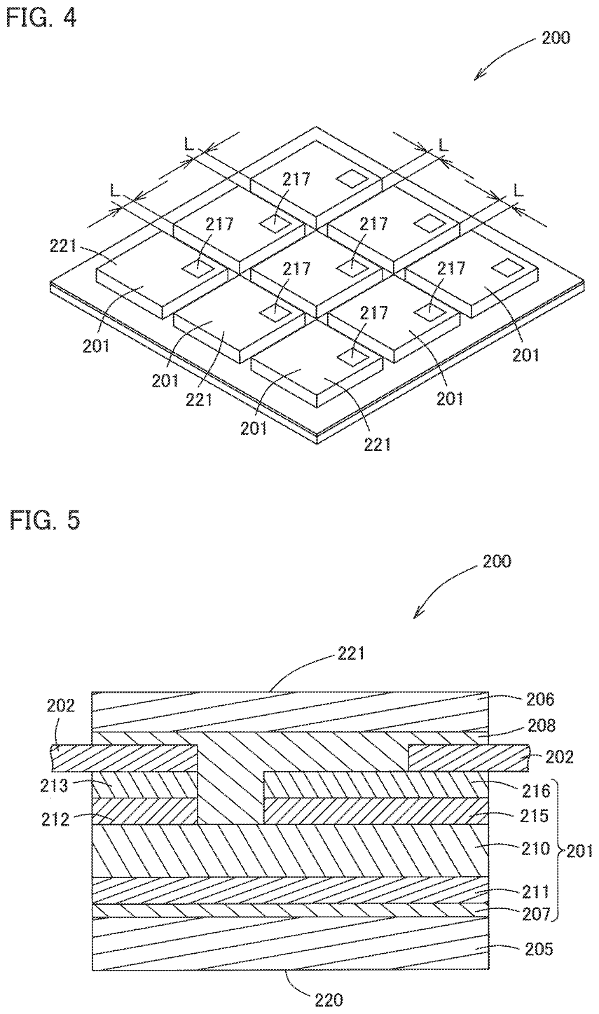

The shortest distance L between the adjacent solar cells 201, 201 of the solar cell module 200 shown in FIG. 4 is preferably 5 mm or less for each in the longitudinal direction and the lateral direction.

With the distance in this range, it is possible to densely lay the solar cells 201 and improve the power generation efficiency per installation area.

As shown in FIG. 2B, the solar cell module 200 of the present embodiment includes a module side identification part 223 on the back surface 221 side.

The module side identification part 223 is a part to which a unique ID is assigned for each solar cell module 200, and is specifically a one-dimensional code or a two-dimensional code. That is, at least the ID assigned to the solar cell module 200 can be detected by identifying the module side identification part 223 with a dedicated reading device.

The solar cell 201 is a so-called back contact solar cell, has electrode layers 213, 216 on the back surface 221 side, and does not have electrode layers 213, 216 on the light receiving surface 220 side as shown in FIG. 5.

Specifically, the solar cell 201 includes an antireflection film 211 (antireflection material) on the light receiving surface 220 side of a first conductivity-type semiconductor substrate 210 (hereinafter, also simply referred to as semiconductor substrate 210). The solar cell 201 also includes a first conductivity-type semiconductor layer 212 and a first conductivity-type side electrode layer 213 disposed in this order in layers on the back surface 221 (main surface opposite to the light receiving surface 220) side of the semiconductor substrate 210. The solar cell 201 further includes a second conductivity-type semiconductor layer 215 and the second conductivity-type side electrode layer 216 disposed in layers on the back surface 221 side of the semiconductor substrate 210 at a site different from the first conductivity-type semiconductor layer 212 and the first conductivity-type side electrode layer 213. The color elements of the solar cells 201 are substantially determined by the antireflection film 211 provided on the light receiving surface 220 side.

The first conductivity-type semiconductor layer 212 has the same conductivity type as that of the semiconductor substrate 210 and has a conductivity type opposite to that of the second conductivity-type semiconductor layer 215. That is, in the solar cell 201, when the first conductivity-type semiconductor layer 212 and the semiconductor substrate 210 are n-type, the second conductivity-type semiconductor layer 215 is p-type, and when the first conductivity-type semiconductor layer 212 and the semiconductor substrate 210 are p-type, the second conductivity-type semiconductor layer 215 is n-type.

The antireflection film 211 is a reflection sealing material that seals received light in the solar cell 201. As the antireflection film 211, for example, silicon nitride or the like can be used.

The refractive index of the antireflection film 211 is preferably an intermediate value between the reflective indexes of the sealing material 207 and the semiconductor substrate 210. That is, the refractive index of the antireflection film 211 is preferably higher than the refractive index of the sealing material 207 and lower than the refractive index of the semiconductor substrate 210.

In the present embodiment, some of the solar cells 201 forming the solar cell module 200 are slightly different in the thickness of the antireflection film 211 and the refractive index of the antireflection film 211 among the solar cells 201 due to the influence of the film formation position of the antireflection film 211, the heating temperature, and the like at the time of manufacturing.

As shown in FIG. 4, the solar cell 201 has a cell side identification part 217 on the back surface 221 side.

The cell side identification part 217 is a part to which a unique ID is assigned, and is specifically a one-dimensional code or a two-dimensional code. That is, at least the ID assigned to the solar cell 201 can be detected by identifying the cell side identification part 217 with a dedicated reading device.

The wiring member 202 is a so-called interconnector, and physically and electrically connects between the adjacent solar cells 201, 201 as shown in FIG. 3.

The first sealing substrate 205 is a sealing member that seals the solar cell 201, and is a translucent insulating substrate or a transparent insulating sheet having translucency and insulation properties, and for example, a substrate made of glass or a transparent resin can be used.

The second sealing substrate 206 is a sealing member that seals the solar cell 201, and is an insulating substrate or an insulating sheet having insulation properties, and for example, a substrate made of glass or a resin can be used.

The sealing material 207, 208 is a translucent adhesive material having translucency and adhesiveness, and for example, an adhesive sheet such as EVA can be used.

Next, a method for manufacturing the solar cell module 200 will be described.

First, the solar cell 201 is formed in the cell formation unit 10 of the manufacturing unit 2 (solar cell formation step, cell formation step).

Specifically, as can be seen from FIG. 5, the first conductivity-type semiconductor layer 212 and the first conductivity-type side electrode layer 213 are disposed in layers in this order on a part of one surface of the semiconductor substrate 210, and the second conductivity-type semiconductor layer 215 and the second conductivity-type side electrode layer 216 are disposed in layers in this order on another part of the same surface. Then, the antireflection film 211 is formed on the opposite surface of the semiconductor substrate 210.

Subsequently, for each solar cell 201 formed in the solar cell formation step, the power generation characteristic measurement unit 30 measures the power generation characteristics, and at the same time, the color element measurement unit 31 measures the color elements (color measurement step).

In the present embodiment, the power generation characteristic measurement unit 30 measures the power generation characteristics such as I-V characteristics and resistance, and the color element measurement unit 31 measures the brightness of each solar cell 201.

The measurement result in the color measurement step for each solar cell 201 is transmitted to the measurement result acquisition unit 22 of the control unit 3 (transmission step), the measurement result in the color measurement step for each solar cell 201 is associated with the cell side identification part 217 of each solar cell 201 by the deep learning unit 20, and stored in the storage unit 21 (association step).

As necessary, after the association step is completed, the solar cell 201 for which the measurement result is associated with the cell side identification part 217 is accommodated in the accommodating unit 11 (accommodating step).

At this time, an accommodating mode in the accommodating unit 11 is not particularly limited. The solar cell 201 may be accommodated in the accommodating unit 11 in the order of manufacture, or may be sorted by each color element and put in different accommodating units 11 for each color element.

Subsequently, the deep learning unit 20 of the control unit 3 determines the arrangement of the solar cells 201 in the solar cell module 200 based on the measurement result received by the measurement result acquisition unit 22 (arrangement determination step).

In the present embodiment, the deep learning section 20 stores the measuring results of the color elements of each of solar cells 201 in the past. It also stores the arrangement of these solar cells 201 in the solar module 200 and the results of human determination of the color balance in the solar module 200 in the past. The results of determination whether the color balance in the solar cell module 200 was good or bad is also stored. Based on such information and the measurement results of the solar cells 201 to be used by the measurement unit 5 are used to determine whether the color balance of the solar cell module 20 to be formed is good or bad. Based on these results, an arrangement model of each of solar cells 201 is generated such that a person can determine that the color balance of the solar cells 201 to be formed is good. Finally, using the model and considering the placement posture of the solar cells 201, the arrangement of the solar cells 201 is determined.

The arrangement operation unit 12 of the manufacturing unit 2 takes out the solar cells 201 from the accommodating unit 11, and arranges the solar cells 201 based on the arrangement model generated by the deep learning unit 20 in the arrangement determination step (arrangement step).

At the time of the arrangement step or after the arrangement step, the wiring member 202 connects between the adjacent solar cells 201, 201 to electrically connect each solar cell 201 (wiring connection step).

At this time, as can be seen from FIGS. 3 and 5, the wiring member 202 connects the first conductivity-type side electrode layer 213 and the second conductivity-type side electrode layer 216 on the back surface 221 side of the adjacent solar cells 201. That is, the wiring member 202 is not connected on the light receiving surface 220 side of the solar cell 201.

Thereafter, a frame, a connector member, and the like are appropriately attached by a known method to complete the solar cell module 200.

Next, the deep learning unit 20 of the present embodiment will be described.

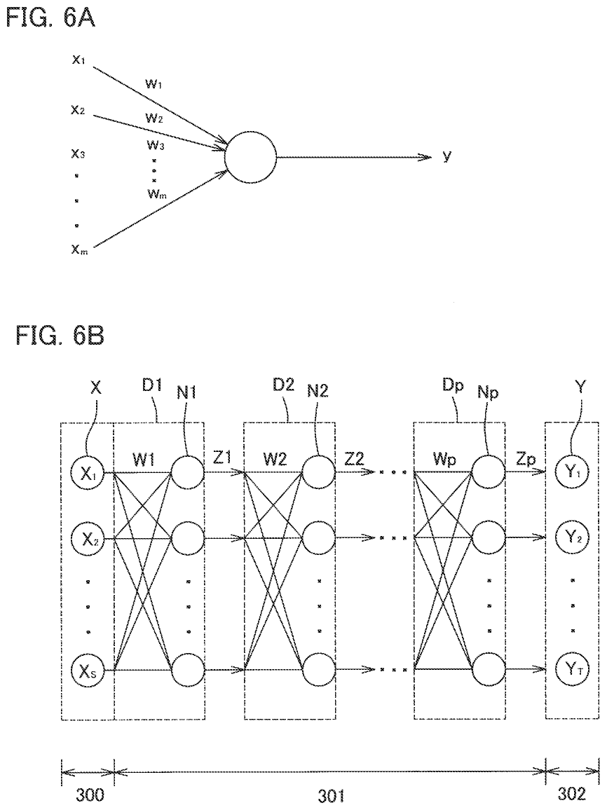

The deep learning unit 20 performs learning according to a neural network of four or more layers, and includes an arithmetic device, a memory, and the like that realize a neural network incorporating a neuron model as shown in FIG. 6A as an approximate algorithm of a value function.

That is, as shown in FIG. 6A, the neuron outputs an output y for m inputs xᵢ (i is a positive integer), and each xᵢ is multiplied by a weight wᵢ corresponding to the input xᵢ and outputs the output y expressed by the following Formula (1). The input xᵢ, the output y, and the weight wᵢ are all vectors.

$$\begin{matrix}[ Formula 1 ] & \\ y = f ( {\sum }_{i = 1}^{m} {w}_{i} {x}_{i} + b ) & ( 1 )\end{matrix}$$

Here, b is a bias, and f is an activation function.

As shown in FIG. 6B, the neural network of the deep learning unit 20 of the present embodiment is a deep neural network including an input layer 300, an intermediate layer 301, and an output layer 302, in which the above-described neurons (neurons N1 to Np) are combined as the intermediate layer 301, and having a thickness of a p layer (p is a positive integer of 4 or more). That is, the intermediate layer 301 includes p intermediate layers D1 to Dp.

In the neural network of the present embodiment, S inputs X (X₁ to X_{S}: S is a positive integer) are input from the input layer 300, and T results Y (Y₁ to Y_{T}: T is a positive integer) are output from the output layer 302 via the intermediate layer 301.

Specifically, each input X (X₁ to X_{S}) of the input layer 300 is multiplied by a corresponding weight W1 and input to each neuron N1 of a first intermediate layer D1 of the intermediate layer 301. Each neuron N1 of the first intermediate layer D1 outputs a feature vector Z1, and the feature vector Z1 is input to each neuron N2 of a second intermediate layer D2 of the intermediate layer 301 after multiplied by a corresponding weight W2.

The feature vector Z1 is a feature vector between the weight W1 and the weight W2, and can be regarded as a vector obtained by extracting a feature amount of the input vector.

The feature vector Z1 is input to each neuron N2 of the second intermediate layer D2 of the intermediate layer 301 after multiplied by the corresponding weight W2.

Each neuron N2 of the second intermediate layer D2 outputs a feature vector Z2, and the feature vector Z2 is input to each neuron N3 of a third intermediate layer D3 of the intermediate layer 301 after multiplied by a corresponding weight W3.

The above processing is repeated in each intermediate layer of the intermediate layer 301, each neuron Np of the P-th intermediate layer Dp at the terminal end outputs a feature vector Zp, and the feature vector Zp is output to the output layer 302. As a result, the neural network outputs results Y (Y₁ to Y_{T}).

The weights W1 to Wp can be learned by an error back propagation method. The error back propagation method is a method of adjusting (learning) each weight W so as to reduce the difference between the output y when the input x is input and the true output y (teacher) for each neuron.

Next, a procedure of machine learning in the deep learning unit 20 will be described.

First, 500 or more of the solar cells 201 (hereinafter also referred to as population solar cells 201a) are manufactured, and the distribution of color element of each solar cell 201 of the population solar cells 201a is calculated.

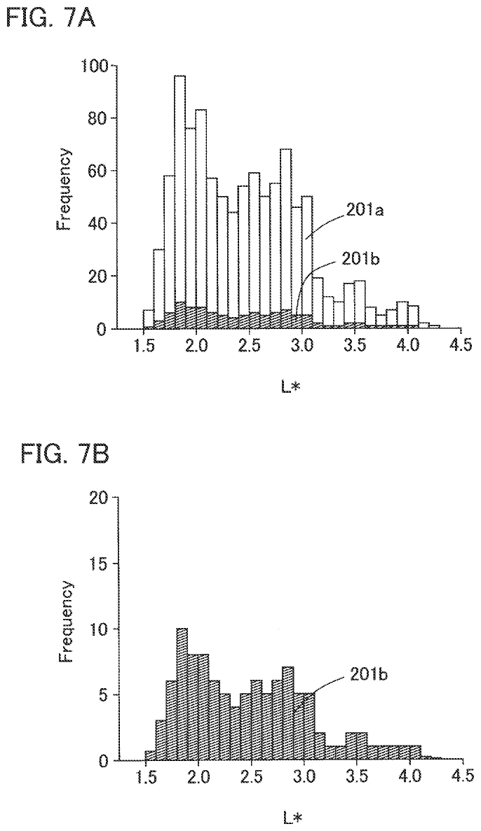

In the present embodiment, as shown in FIG. 7, the distribution of the brightness of each solar cell 201 of the population solar cells 201a having 1000 cells is calculated.

Next, as shown in FIGS. 7A and 7B, a predetermined number (for example, 30) of the solar cells 201 (hereinafter also referred to as sample solar cells 201b) are extracted as samples from the population solar cells 201a such that the brightness distribution of the population solar cells 201a is substantially maintained, and the sample solar cells 201b are randomly arranged to assemble the solar cell module 200.

The phrase “a predetermined number of solar cells are extracted such that the brightness distribution is substantially maintained” as used herein means that when the brightness distribution of a predetermined number of solar cells as a sample is acquired, the tendency of the brightness distribution coincides with the tendency of the brightness distribution of the population.

The arrangement of each solar cell 201 and the color elements of each solar cell 201 are input to the input layer 300 of the deep learning unit 20, and the result of determination on the quality of the color balance is acquired from the output layer 302. In addition, the solar cell module 200 is viewed by one or a plurality of judge in a separate process, and quality determination is performed.

At this time, in the present embodiment, the judge uses the brightness as a determination criterion, and determines the quality of the color balance from the brightness balance.

Then, the quality determination result acquired from the output layer 302 of the deep learning unit 20 is compared with the quality determination result determined by the judge. The weight is adjusted so that the differences of the quality determination results match. The arrangement of the solar cells 201 is replaced and then machine learning is performed.

Next, representative physical properties of the solar cell module 200 manufactured by the module manufacturing apparatus 1 of the present embodiment will be described.

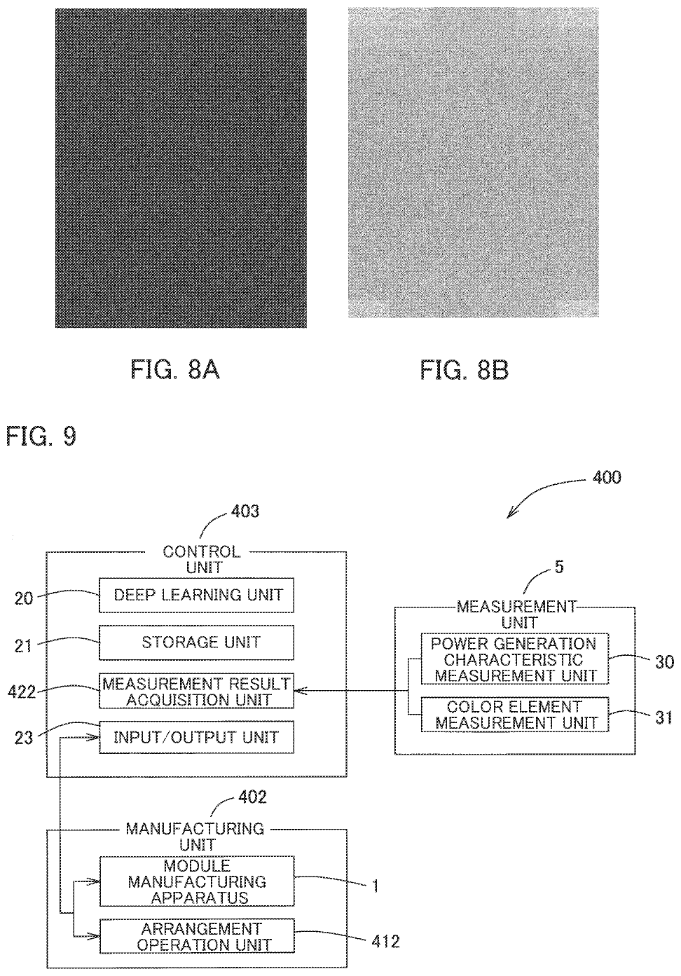

The solar cell module 200 has a low entire brightness and looks uniform as shown in FIG. 8A in a place with low illuminance such as the indoor condition, and does not cause the user to feel color unevenness as shown in FIG. 8B even in a place with high illuminance such as the outdoor condition.

Here, as a measure for showing a color of an object, the CIE 1976 (L*, a*, b*) color system is usually used. However, the CIE 1976 (L*, a*, b*) color system is not suitable for the purpose of quantifying the difference in appearance caused by the difference in illumination environment to an object.

Therefore, the CIE 1976 (L*, a*, b*) color system cannot be used for the purpose of quantifying the appearance of an object that is particularly noticeable under conditions of high illuminance, such as direct sunlight outdoors as described above.

The inventor therefore has studied a method of numerically expressing an object color under direct sunlight in an outdoor environment. The displaying way of color of an object in the present specification reflects the result of the above study, and specifically, numerical values measured under the following conditions are used.

A solar simulator is prepared as a light source, and an object is vertically irradiated with light of AM1.5 having a radiation intensity of 1000 W/m². A camera is prepared as a measurement device, and is installed at a position facing the object as much as possible under a condition that regular reflection light does not enter the object.

The camera is set as follows, and a JPEG image of the object is taken with the camera. The RGB value of each pixel of the object is read from the taken JPEG image. The read RGB values are converted into the CIE 1976 (L*, a*, b*) color system using a white point of Illuminant D 65 with a 100 degree field of vision.

[Camera Setting]

In a state where a standard lens NIKKOR 18-55 mm 1:3.5-5.6 GI lens is mounted on a digital camera D5500 manufactured by Nikon Corporation, the aperture value is set to 8, the film sensitivity to ISO400, the shutter speed to 1/100 seconds, white balance to “sunny”, the picture control to “standard”, the color space to sRGB, the active D-lighting to OFF, and the high dynamic range to OFF.

The chromaticity coordinates in the CIE 1976 (L*, a*, b*) color system described below are coordinates obtained by quantifying the object color by the above method.

The solar cell module 200 preferably satisfies any one of the following conditions (1) to (3) in the CIE 1976 (L*, a*, b*) color system calculated from an image obtained by photographing the solar cell under direct sunlight irradiation.

(1) The difference between the maximum value and the minimum value of the brightness L* of each solar cell 201 is 3.0 or more, and the difference in the brightness L* between the adjacent solar cells 201, 201 is 1.5 or less.

(2) The difference between the maximum value and the minimum value of the chromaticity a* of each solar cell 201 is 2.0 or more, and the difference in the chromaticity a* between the adjacent solar cells 201, 201 is 1.0 or less.

(3) The difference between the maximum value and the minimum value of the chromaticity b* of each solar cell 201 is 5.0 or more, and the difference in the chromaticity b* between the adjacent solar cells 201, 201 is 2.5 or less.

In the solar cell module 200, one solar cell 201 is disposed so as to be adjacent to and surrounded by at least three solar cells 201, and the relationship between the one solar cell 201 and the three solar cells 201 preferably satisfies any one of the following conditions (4) to (6) in the CIE 1976 (L*, a*, b*) color system.

(4) The condition (1) is satisfied, and the difference in the brightness L* between the one solar cell 201 and the three solar cells 201 is 1.8 or less.

(5) The condition (2) is satisfied, and the difference in the chromaticity a* between the one solar cell 201 and the three solar cells 201 is 1.5 or less.

(6) The condition (3) is satisfied, and the difference in the chromaticity b* between the one solar cell 201 and the three solar cells 201 is 4.0 or less.

The values of the brightness L*, the chromaticity a*, and the chromaticity b* may be values at one measurement point or may be average values measured at a plurality of measurement points.

In the condition (6), it is preferable that the condition (3) is satisfied, and the difference in the chromaticity b* between the one solar cell 201 and the three solar cells 201 is preferably 2.0 or less.

As described above, the solar cells 201 manufactured by the manufacturing unit 2 of the module manufacturing apparatus 1 of the present embodiment are formed through the same manufacturing process, but a disarray in color element occurs between the solar cells 201, 201 due to a difference in thickness of the antireflection film 211 or in refractive index of the antireflection film 211.

According to the module manufacturing apparatus 1 of the present embodiment, a subjective determination by humans on color balance is performed in the deep learning unit 20, and the deep learning unit 20 generates an arrangement model that is predicted to have a good color balance of the solar cell module 200, considering the slight disarray in color element between the solar cells 201 described above. Therefore, it is possible to set an arrangement of the solar cells 201 having homogeneity, considering the illusion of human eyes (optical illusion) Thus, more solar cells 201 can be used for manufacturing the solar cell module 200. Therefore, it is possible to improve the yield as compared with the case of simply arranging solar cells having similar color distributions.

In addition, according to the module manufacturing apparatus 1 of the present embodiment, a determination on color balance close to human sensitivity in the module manufacturing apparatus 1 can be performed, which eliminates a necessity of a determination by humans on the arrangement, and enables automated arrangement of the solar cells 201.

According to the solar cell 201 of the present embodiment, the wiring member 202 is provided on the side opposite to the light receiving surface 220, that is, on the back surface 221 side, which prevents the wiring member 202 from interfering with the reception of sunlight or the like, and enables an improved power generation efficiency as compared with the case where the wiring member 202 is provided on the light receiving surface 220 side.

The module manufacturing apparatus 1 of the present embodiment uses the variation in brightness as the criterion for determining the color balance, which enables a better color balance under sunlight such as outdoors and a further improved design property.

According to the module manufacturing apparatus 1 of the present embodiment, the sample solar cells 201b are acquired such that the distribution is substantially maintained from the color distribution of the population solar cells 201a whose tendency is smoothed, which enables a more accurate machine learning.

The solar cell module 200 of the present embodiment has a large absolute value of the color element of at least one of the brightness L*, the chromaticity a*, and the chromaticity b* of each solar cell 201, and has a variation in color element of the entire solar cells 201. That is, when the solar cells are simply arranged, there is no uniformity in color element, and color unevenness occurs.

According to the solar cell module 200 of the present embodiment, the difference in color element of at least one of the brightness L*, the chromaticity a*, and the chromaticity b* of the adjacent solar cells 201, 201 is small even when there is a variation in color element of the entire solar cells 201, and therefore the solar cell module is coherent and has homogeneity as a whole and uniformity in color element is obtained.

In the solar cell module 200 of the present embodiment, a difference in color element of at least one of the brightness L*, the chromaticity a*, and the chromaticity b* between one solar cell 201 and the solar cell 201 adjacent to each side of the one solar cell 201 is small, and therefore the solar cell module has more uniformity in color element.

In the solar cell module 200 of the present embodiment, the solar cells 201 are arranged in a grid pattern, and the interval between the adjacent solar cells 201, 201 is narrow, and therefore the solar cell module has more uniformity in color element.

According to the method for manufacturing the solar cell module 200 of the present embodiment, the arrangement of the solar cells 201 is determined using the measurement result in the color measurement step of measuring color elements and, and therefore the solar cell module 200 having a good color balance based on the measurement result of color elements can be manufactured.

According to the method for manufacturing the solar cell module 200 of the present embodiment, in the arrangement determination step, the arrangement of the solar cells 201 is determined such that each solar cell 201 has a good color balance from the measurement result in the color measurement step based on the color elements of each solar cells 201 of the solar cell module 200 measured in the past. Therefore, each solar cell 201 has a good color balance as compared with the case where the solar cells 201 are randomly arranged.

According to the method for manufacturing the solar cell module 200 of the present embodiment, in the arrangement step, based on the arrangement model determined by the deep learning unit 20 in the arrangement determination step, the solar cell 201 associated with the measurement result in the association step is taken out from the accommodating unit 11 and arranged. Therefore, the solar cells 201 accommodated in the accommodating unit 11 and temporarily stocked can be taken out at necessary timing.

According to the method for manufacturing the solar cell module 200 of the present embodiment, the color elements and power generation characteristics of the solar cell 201 are simultaneously measured in the color measurement step, and therefore a defective product can be excluded before the solar cell is accommodated in the accommodating unit 11, which can shorten the manufacturing time.

According to the method for manufacturing the solar cell module 200 of the present embodiment, in the arrangement determination step, the arrangement posture (which side is directed to which position or the like) of the solar cells 201 to be arranged is determined based on the measurement result. Therefore, more kinds of solar cells 201 can be used for the solar cell module 200.

According to the method for manufacturing the solar cell module 200 of the present embodiment, in the color measuring step, the color elements of the solar cells 201 are measured at a plurality of measurement points, and in the arrangement determination step, the arrangement of the solar cells 201 is determined using the average value of the color elements, therefore the arrangement of the solar cells 201 can be determined more accurately.

Next, a wall surface manufacturing apparatus 400 according to a second embodiment of the present invention will be described. The same components as those of the module manufacturing apparatus 1 of the first embodiment are denoted by the same reference signs, and the description thereof will be omitted. The same applies hereinafter.

As shown in FIG. 10, the wall surface manufacturing apparatus 400 of the second embodiment forms a wall surface structure 500 (solar cell group) in which a plurality of solar cell modules 200 (solar cells) are planarly arranged.

Similarly to the module manufacturing apparatus 1 according to the first embodiment, the wall surface manufacturing apparatus 400 also includes the deep learning unit 20, and an arrangement model of the solar cell module 200 is generated based on a result of machine learning performed in advance by the deep learning unit 20. One of the features of the wall surface manufacturing apparatus 400 is that the solar cell module 200 is arranged and manufactured according to the generated arrangement model.

That is, the module manufacturing apparatus 1 according to the first embodiment forms the arrangement model of each solar cell 201 by the deep learning unit 20 and adjusts the color balance of the solar cell module 200, whereas the wall surface manufacturing apparatus 400 according to the second embodiment adjusts the arrangement of each solar cell module 200 by the deep learning unit 20 to adjust the color balance of a wall surface structure 500.

In the module manufacturing apparatus 1 of the first embodiment, the “solar cell group” according to the present invention corresponds to the solar cell module 200, and the “solar cell” corresponds to the solar cell 201, whereas in the wall surface manufacturing apparatus 400 of the second embodiment, the “solar cell group” according to the present invention corresponds to the wall surface structure 500, and the “solar cell” corresponds to the solar cell module 200.

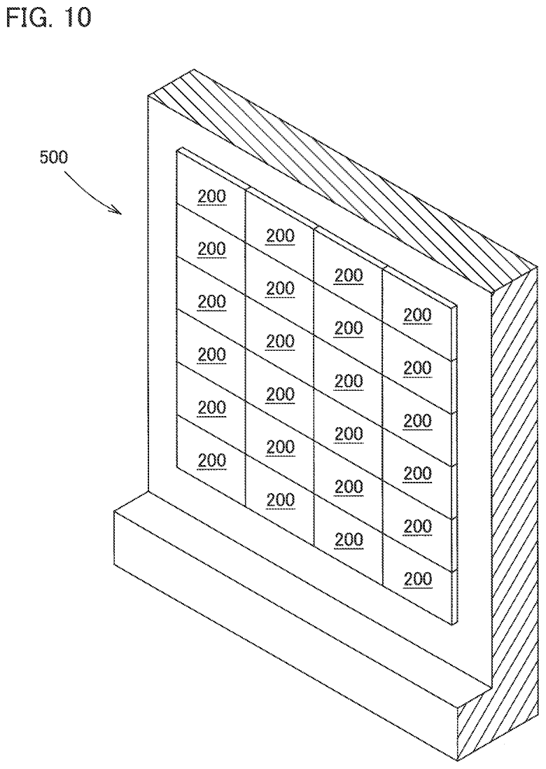

The wall surface manufacturing apparatus 400 includes a manufacturing unit 402, a control unit 403, and a measurement unit 5 as shown in FIG. 9.

The manufacturing unit 402 includes the module manufacturing apparatus 1 and an arrangement operation unit 412 as main components.

The arrangement operation unit 412 is a part that arranges the solar cell module 200 based on an arrangement model formed by the deep learning unit 20 of the control unit 403.

The control unit 403 includes the deep learning unit 20, the storage unit 21, a measurement result acquisition unit 422, and the input/output unit 23.

The deep learning unit 20 of the present embodiment can perform machine learning by itself using the color elements and the arrangement of each solar cell module 200 as well as the result of determination by humans on the color balance of the wall surface structure 500 as training data, and can create an arrangement model of the solar cell modules 200 that is expected to be determined as having a good color balance by humans from the color elements of each solar cell module 200 acquired by the measurement result acquisition unit 422 based on the result of the machine learning.

The procedure of the machine learning in the deep learning unit 20 is the same except that the solar cell 201 of the first embodiment is replaced to the solar cell module 200 of the second embodiment and the solar cell module 200 of the first embodiment is replaced to the wall surface structure 500 of the second embodiment, and thus the description thereof is omitted.

The measurement result acquisition unit 422 is a part that acquires the measurement results of the power generation characteristics, the color elements, and the like measured by the measurement unit 5 and transmits the measurement results to the storage unit 21 and/or the deep learning unit 20.

The measurement unit 5 of the present embodiment is a part that measures the characteristics of the solar cell module 200 formed by the module manufacturing apparatus 1 of the manufacturing unit 402, and includes the power generation characteristic measurement unit 30 and the color element measurement unit 31, and the measurement target of the measurement units 30 and 31 is the solar cell module 200.

Next, the wall surface structure 500 to be manufactured will be described.

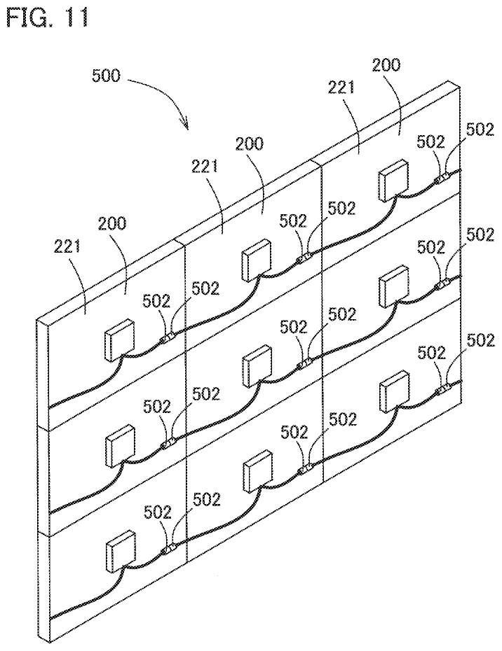

In the wall surface structure 500, a plurality of solar cell modules 200 are planarly arranged as shown in FIG. 11, and each solar cell module 200 is electrically connected by a connector member 502 provided on the back surface 221. In the wall surface structure 500 of the present embodiment, 20 or more of the solar cell modules 200 in total are arranged in a grid pattern.

The shortest distance between the adjacent solar cell modules 200, 200 is preferably 5 cm or less, more preferably 2 cm or less, and particularly preferably 5 mm or less.

With the distance in this range, it is possible to densely lay the solar cell modules 200 and improve the power generation efficiency per installation area.

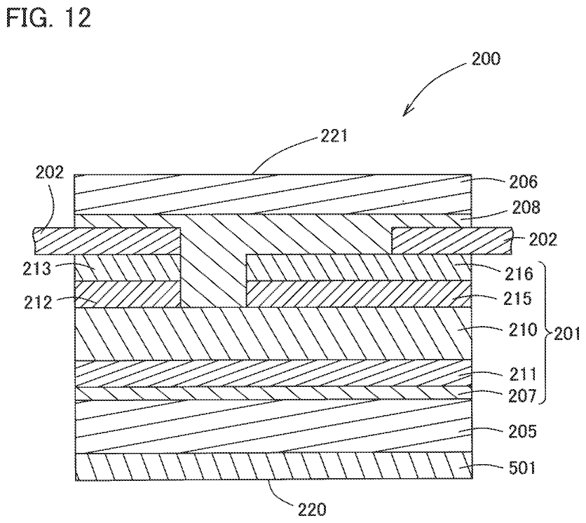

In the solar cell module 200 of the present embodiment, a second antireflection film 501 (antireflection material) is formed on the sealing substrate 205 on the light receiving surface 220 side as shown in FIG. 12. That is, in the solar cell module 200 of the present embodiment, the antireflection film 211 is interposed between the sealing substrate 205 on the light receiving surface 220 side and the solar cell 201, and the second antireflection film 501 is formed on the outer surface of the sealing substrate 205 on the light receiving surface 220 side with respect to the solar cell 201.

Next, a method of manufacturing the wall surface structure 500 will be described.

First, the solar cell module 200 is formed by the module manufacturing apparatus 1 of the manufacturing unit 402 (solar cell module formation step).

At this time, the second antireflection film 501 is formed on the outer surface of the sealing substrate 205 on the light receiving surface 220 side.

Subsequently, for each solar cell module 200 formed in the solar cell module formation step, the power generation characteristic measurement unit 30 measures the power generation characteristics, and at the same time, the color element measurement unit 31 measures the color elements (color measurement step).

The measurement result of the solar cell module 200 in the color measurement step is transmitted to the measurement result acquisition unit 422 of the control unit 403 (transmission step), the measurement result in the color measurement step of the solar cell module 200 is associated with the module side identification part 223 for each solar cell module 200 by the deep learning unit 20, and stored in the storage unit 21 (association step).

Subsequently, the deep learning unit 20 of the control unit 403 determines the arrangement of the solar cell modules 200 in the wall surface structure 500 based on the measurement result received by the measurement result acquisition unit 422 (arrangement determination step).

Specifically, as in the first embodiment, based on the color elements of each solar cell module 200 and the arrangement of each solar cell modules 200 wall in the surface structure 500 measured by the deep learning unit 20 in the past and the result of determination by humans on the quality of the color balance of wall surface structure 500 in the past, an arrangement model of each solar cell module 200 is generated and the arrangement is determined from the measurement result of the measurement unit 5 of each solar cell module 200 so that humans determine that the color balance of the wall surface structure 500 to be formed is good.

The arrangement operation unit 412 of the manufacturing unit 402 arranges the solar cell module 200 based on the arrangement model generated by the deep learning unit 20 in the arrangement determination step (arrangement step).

At the time of the arrangement step or after the arrangement step, the connector member 502 provided on the back surface 221 connects between the adjacent solar cell modules 200, 200 to electrically connect each solar cell module 200 as shown in FIG. 11 (connector connecting step).

Thereafter, crosspieces and the like are appropriately attached by a known method to complete the wall surface structure 500.

The solar cell modules 200 in this embodiment are formed through the same manufacturing process. However, a disarray in color element occurs between the solar cells 200, 200 due to a difference in thickness of the antireflection film 211, 501 or in refractive index of the antireflection film 211, 501.

According to the wall surface manufacturing apparatus 400 of the present embodiment, a subjective determination by humans on color balance is performed in the deep learning unit 20, and the deep learning unit 20 generates an arrangement model that is predicted to be determined as having a good color balance of the wall surface structure 500 considering the slight disarray in color element between the solar cell modules 200 described above. Therefore, it is possible to set an arrangement of the solar cell modules 200 having homogeneity in consideration of the illusion of human eyes, and more solar cell modules 200 can be used for manufacturing the wall surface structure 500. Therefore, it is possible to improve the yield as compared with the case of simply arranging solar cells having similar color distributions.

In addition, according to the wall surface manufacturing apparatus 400 of the present embodiment, a determination on color balance close to human sensitivity in the wall surface manufacturing apparatus 400 can be performed, which enables automation of the arrangement of the solar cell modules 200.

According to the wall surface manufacturing apparatus 400 of the present embodiment, the wall surface structure 500 is formed by arranging the solar cell modules 200, which improves color balance, in particular, uniformity in color element in a wide range.

The wall surface structure 500 of the present embodiment has a large absolute value of the color element of at least one of the brightness L*, the chromaticity a*, and the chromaticity b* of each solar cell module 200, and has a variation in color element of the entire solar cell module 200. That is, when the solar cells are simply arranged, there is no uniformity in color element, and color unevenness occurs.

According to the wall surface structure 500 of the present embodiment, the difference in color element of at least one of the brightness L*, the chromaticity a*, and the chromaticity b* of the adjacent solar cell modules 200, 200 is small even with a variation in color element of the entire solar cells 200, and therefore the wall surface structure is coherent and has homogeneity as a whole and uniformity in color element.

According to the method for manufacturing the wall surface structure 500 of the present embodiment, the arrangement of the solar cell modules 200 is determined using the measurement result in the color measurement step of measuring color elements, and therefore the wall surface structure 500 having a good color balance based on the measurement result of color elements can be manufactured.

Next, a manufacturing apparatus 600 according to a third embodiment of the present invention will be described.

In the manufacturing apparatus 600 of the third embodiment, a control unit 603 is different in structure from the control unit 3 of the first embodiment.

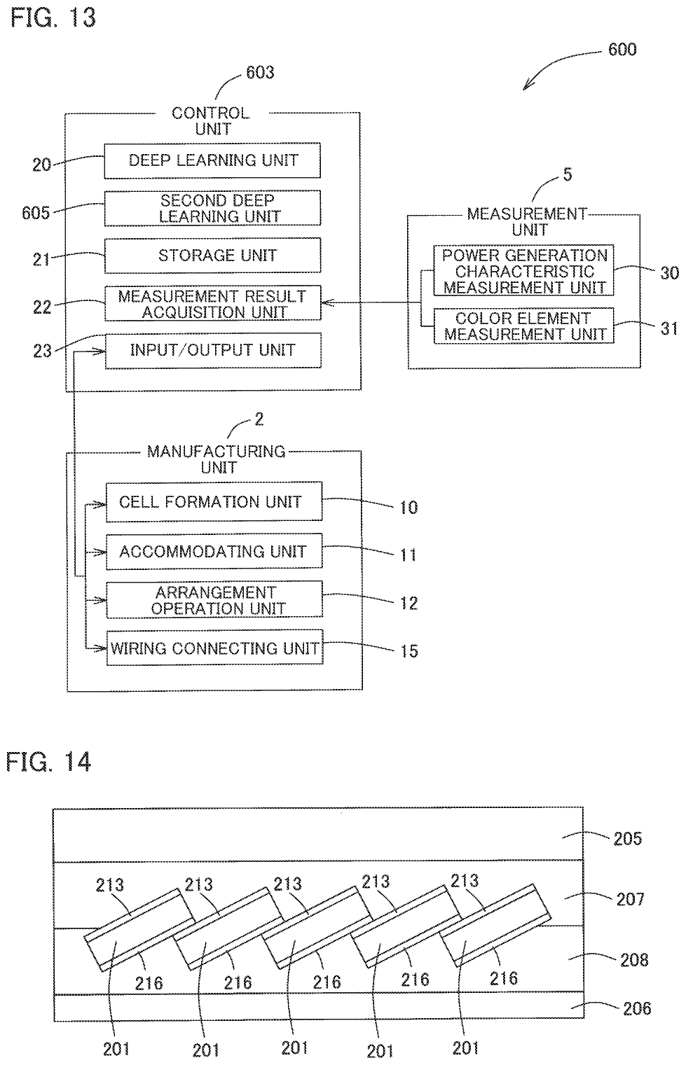

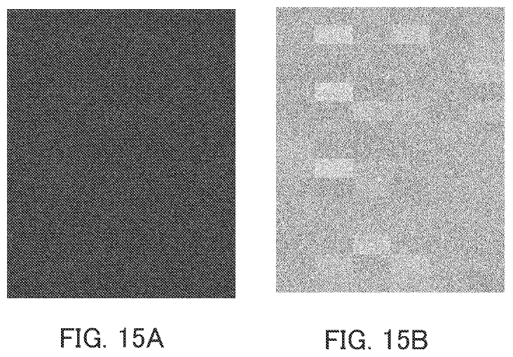

That is, as shown in FIG. 13, the control unit 603 of the manufacturing apparatus 600 includes a second deep learning unit 605 (second machine learning unit) in addition to the deep learning unit 20 (machine learning unit), the storage unit 21, the measurement result acquisition unit 22, and the input/output unit 23 as main components, and the second deep learning unit 605 generates an arrangement model of the solar cells 201.

The second deep learning unit 605 replaces the arrangement of each solar cell 201 in the solar cell module 200 and provides the deep learning unit 20 with the information of the color elements of each solar cell 201 when replaced so as to cause the deep learning unit 20 to determine the color balance of the solar cell module 200. Then, the second deep learning unit 605 uses the plurality of correlation data between the arrangement of the solar cells 201 and the determination result determined by the deep learning section 20 as the training data to perform machine learning.

The second deep learning unit 605 can generate an arrangement model (second arrangement model) of the solar cells 201 that is predicted to be determined by the deep learning unit 20 that the solar cell module 200 has a better color balance.

Similar to the deep learning unit 20, the second deep learning unit 605 performs learning with a neural network of four or more layers. Similar to the deep learning unit 20, the neural network of the second deep learning unit 605 includes the input layer 300, the intermediate layer 301, and the output layer 302, wherein the above-described neurons (neurons N1 to Np) are included in the intermediate layer 301, the neurons having a p layer thickness (p is a positive integer of 4 or more).

Next, a procedure of machine learning in the second deep learning unit 605 will be described.

First, the population solar cells 201a are manufactured, and the distribution of color elements of each solar cell 201 of the population solar cells 201a is calculated.

Subsequently, the sample solar cells 201b are extracted as samples from the population solar cells 201a such that the brightness distribution of the population solar cells 201a is substantially maintained, and the sample solar cells 201b are randomly arranged to assemble the solar cell module 200.

The arrangement of each solar cell 201 and the color elements of each solar cell 201 are input to the input layer 300 of the second deep learning unit 605, and the result of determination on the quality of the color balance is acquired from the output layer 302. In addition, the deep learning unit 20 determines the quality of the solar cell module 200.

Then, the quality determination result acquired from the output layer 302 of the second deep learning unit 605 is compared with the quality determination result determined by the deep learning unit 20, the weight is adjusted so that the differences of the quality determination results match, the arrangement of the solar cells 201 is replaced, and machine learning is performed.

The deep learning unit 20 of the present embodiment performs machine learning in advance for a correlation between the color elements and arrangement of the solar cells 201, and a result of determination by humans on the color balance of the solar cell module 200, as training data, thus having a determination criterion close to human subjective view.

According to the manufacturing apparatus 600 of the present embodiment, the second deep learning unit 605 performs machine learning based on the determination on color balance by the deep learning unit 20e, which is close to human subjective view. The second deep learning unit 605 generates an arrangement model that is predicted to be determined that the solar cell module 200 has a good color balance. Therefore, it is possible to set an arrangement considering the illusion of human eyes, and more solar cells 201 can be used for manufacturing the solar cell module 200. Therefore, it is possible to improve the yield as compared with the case of simply arranging solar cells having similar color distributions.

According to the manufacturing apparatus 600 of the present embodiment, the deep learning unit 20 gives the training data to the second deep learning unit 605, and therefore it is possible to give the training data to the second deep learning unit 605 without a determination by humans.

In the embodiments described above, a case where a back contact solar cell 201 in which the electrode layers 213, 216 and the wiring member 202 are provided on the back surface 221 side is used as the solar cell 201 is described, but the present invention is not limited to this. As the solar cell 201, another kind of solar cell in which an electrode layer and a wiring member are provided on the light receiving surface 220 side can also be used.

In the embodiments described above, the solar cells 201 are electrically connected by the wiring member 202, but the present invention is not limited to this. The adjacent solar cells 201, 201 may partially overlap, and the electrode layers 213, 216 may be in direct contact with each other and electrically connected as shown in FIG. 14.

In the first and third embodiments described above, the solar cell 201 is provided with the cell side identification part 217 on the back surface 221 side, but the present invention is not limited to this. The cell side identification part 217 may be provided on the light receiving surface 220 side.

In the first embodiment described above, each solar cell 201 is identified by providing the cell side identification part 217 on the back surface 221 side of the solar cell 201, but the present invention is not limited to this. The solar cell 201 may be identified by information such as an accommodating position of the solar cell 201 on a manufacturing line. In this case, the cell side identification part 217 does not have to be provided on the solar cell 201.

In the second embodiment described above, the solar cell module 200 is provided with the module side identification part 223 on the back surface 221 side, but the present invention is not limited to this. The module side identification part 223 may be provided on the light receiving surface 220 side.

In the second embodiment described above, each solar cell module 200 is identified by providing the module side identification part 223 on the back surface 221 side of the solar cell module 200, but the present invention is not limited to this. The solar cell module 200 may be identified by information such as an accommodating position of the solar cell module 200 on a manufacturing line. In this case, the module side identification part 223 does not have to be provided on the solar cell module 200.

In the above embodiment, as the solar cell 201, the semiconductor substrate 210 of one conductivity type and the second conductivity-type semiconductor layer 215 of opposite conductivity type are directly joined to form a pn junction, but the present invention is not limited to this. The solar cell 201 may be a heterojunction solar cell in which an intrinsic semiconductor layer is interposed between the first conductivity-type semiconductor substrate 210 and the second conductivity-type semiconductor layer 215. In this case, the thickness of the intrinsic semiconductor layer or the like may somewhat affect the apparent color elements between the solar cells 201. In this case, the deep learning unit 20 generates an arrangement model predicted to be determined as having a good color balance considering the intrinsic semiconductor layer.

In the first embodiment described above, the entire light receiving surface 220 of the solar cell 201 is covered with the antireflection film 211, but the present invention is not limited to this. A part of the light receiving surface 220 of the solar cell 201 may be covered with the antireflection film 211.

In the first embodiment described above, determination by humans on the color balance of the solar cell module 200 uses training data that is divided in a plurality of stages, but the present invention is not limited to this. A determination by humans may use training data that is only whether the color balance of the solar cell module 200 is good or not good.

In the second embodiment described above, the second antireflection film 501 is formed on the surface of the sealing substrate 205 on the light receiving surface 220 side, but the present invention is not limited to this. The second antireflection film 501 does not have to be formed on the surface of the sealing substrate 205 on the light receiving surface side.

In the second embodiment described above, the solar cells 201 are separately and independently provided as the solar cell module 200, electrically connected by the wiring member 202, and sealed by the sealing substrates 205, 206, but the present invention is not limited to this. As the solar cell module 200, a thin film solar cell in which each layered solar cell is formed on a sealing supporting substrate may be used.

In the first and third embodiments described above, when humans or the deep learning unit 20 determines the color balance of the solar cell module 200, the color balance is determined based on the brightness, but the present invention is not limited to this. The color balance may be determined based on chromaticity when humans or the deep learning unit 20 determines the color balance of the solar cell module 200. The color balance may also be determined based on a design, a pattern, or the like formed between the solar cells 201.

Similarly, in the second embodiment, when humans determine the color balance of the wall surface structure 500, the color balance is determined based on the brightness, but the present invention is not limited to this. The color balance may be determined based on chromaticity when humans determine the color balance of the wall surface structure 500. The color balance may also be determined based on a design, a pattern, or the like formed between the solar cell modules 200.

In the embodiments described above, the case of the deep learning units 20, 605 that perform learning according to the algorithm of a deep neural network of four or more layers as the machine learning unit and the second machine learning unit of the present invention is described, but the present invention is not limited to this. The learning may be performed according to an algorithm of a neural network of three or less layers.

In the first and second embodiments described above, the arrangement of the solar cells 201 or the solar cell modules 200 is determined based on the result of machine learning of the deep learning unit 20, but the present invention is not limited to this. The arrangement may be mechanically determined by referring to the arrangement and the color elements measured in the past as well as the result of determination by humans on the arrangement and the color elements.

In the embodiment described above, each constituent member can be freely replaced or added between the embodiments as long as it is included in the technical scope of the present invention.

### EXPLANATION OF REFERENCE SIGNS

1, 600: module manufacturing apparatus
12, 412: arrangement operation unit
20: deep learning unit (machine learning unit)
31: color element measurement unit
200: solar cell module
201: solar cell
201a: population solar cell
201b: sample solar cell
202: wiring member
205: first sealing substrate
206: second sealing substrate
207, 208: sealing material
211: antireflection film
220: light receiving surface
221: back surface
400: wall surface manufacturing apparatus
500: wall surface structure (solar cell group)
501: second antireflection film
502: connector member
605: second deep learning unit (second machine learning unit)

1. A manufacturing apparatus for a solar cell group, comprising:
an arrangement operation unit that arranges a plurality of solar cells constituting the solar cell group; and
a machine learning unit,
wherein the solar cell group includes a plurality of solar cells arranged planarly,
wherein the plurality of solar cells each include: a light receiving surface; and an antireflection material on a light receiving surface side,
wherein the plurality of solar cells include a first solar cell having a variation in a color element due to a difference in thickness of the antireflection material or a difference in refractive index of the antireflection material,
wherein the machine learning unit performs machine learning using a correlation between an arrangement of the plurality of solar cells and a determination result by humans on color balance of the solar cell group under the arrangement as training data,
wherein when the solar cell group is manufactured, the machine learning unit generates an arrangement model of the solar cells, the arrangement model being predicted to be determined to have a good color balance as the solar cell group by humans' visual recognition based on information on color elements of each of the solar cells, and
wherein the arrangement operation unit arranges each of the solar cells based on the arrangement model.

2. The manufacturing apparatus for the solar cell group according to claim 1,
wherein the solar cell group is a solar cell module that includes the plurality of solar cells electrically connected by a wiring member, and
wherein each of the solar cells is connected by the wiring member on a side opposite to the light receiving surface.

3. The manufacturing apparatus for the solar cell group according to claim 1,
wherein the solar cell is a solar cell module including the plurality of solar cells sandwiched between two sealing members, and
wherein the sealing member on the light receiving surface side has translucency, the antireflection material being interposed between the sealing member and the solar cells.

4. The manufacturing apparatus for the solar cell group according to claim 1,
wherein the plurality of solar cells include a second solar cell having variation in brightness due to the difference in thickness of the antireflection material or the difference in refractive index of the antireflection material,
wherein the machine learning unit performs machine learning using a correlation between the arrangement of the plurality of solar cells and a determination result by humans on the variation in brightness of the solar cell group under the arrangement, as training data, and
wherein when the solar cell group is manufactured, the machine learning unit generates an arrangement model of the solar cells, the arrangement model being predicted to be determined to have a small variation in brightness of the plurality of solar cells in the solar cell group by humans' visual recognition based on information on brightness of each solar cell.

5. The manufacturing apparatus for the solar cell group according to claim 1,
wherein the apparatus acquires a distribution of color elements of 500 or more solar cells and extracting a predetermined number of the solar cells from the 500 or more solar cells such that the distribution of the color elements is substantially maintained, and
wherein the machine learning unit performs machine learning using a correlation between an arrangement of the predetermined number of solar cells and a determination result by humans on color balance under the arrangement, as training data.

6. The manufacturing apparatus for the solar cell group according to claim 1,
wherein the machine learning unit is capable of predicting a determination result on the color balance of the solar cell group when viewed by humans based on information on color elements and arrangement of each of the solar cells,
wherein the apparatus includes a second machine learning unit,
wherein the second machine learning unit replaces the arrangement of the plurality of solar cells in the solar cell group to provide the machine learning unit with the information on color elements and arrangement of each of the solar cells when replaced, thereafter making the machine learning unit perform machine learning to determine the color balance of the solar cell group, then performing machine learning using a correlation between the arrangement of the plurality of solar cells and a determination result by the machine learning unit as training data,
wherein when the solar cell group is manufactured, the second machine learning unit generates a second arrangement model of the solar cells, the second arrangement model being predicted to be determined to have a color balance of the solar cell group better than that by the machine learning unit, and
wherein when the second machine learning unit generates the second arrangement model, the arrangement operation unit arranges each of the solar cells based on the second arrangement model.

7. A solar cell group including 20 or more solar cells planarly arranged in total, wherein each of the solar cells includes a light receiving surface and an antireflection material on a light receiving surface side,
wherein the plurality of solar cells include a first solar cell having a variation in color element due to a difference in thickness of the antireflection material or a difference in refractive index of the antireflection material, and
wherein the solar cell group satisfies the following condition (1) or (2) in CIE 1976 (L*, a*, b*) color system calculated from an image obtained by photographing the solar cells under irradiation of direct sunlight:
(1) a difference between a maximum value and a minimum value of brightness L* of each solar cell is 2.0 or more, and a difference in brightness L* between adjacent solar cells is 1.5 or less;
(2) a difference between a maximum value and a minimum value of chromaticity b* of each solar cell is 4.0 or more, and a difference in chromaticity b* between adjacent solar cells is 1.5 or less.

8. The solar cell group according to claim 7,
wherein the solar cells includes a second solar cell disposed adjacent to at least three of the solar cells, and
wherein the solar cell group satisfies the following condition (3) or (4) in the CIE 1976 (L*, a*, b*) color system calculated from an image obtained by photographing the solar cells under irradiation of direct sunlight:
(3) the condition (1) is satisfied, and a difference in the brightness L* between the second solar cell and the three of the solar cells is 1.8 or less;
(4) the condition (2) is satisfied, and a difference in the chromaticity b* between the second solar cell and the three of the solar cells is 2.0 or less.

9. The solar cell group according to claim 7, wherein each of the brightness L* and the chromaticity b* of each of the solar cells is an average value measured at a plurality of measurement points in the solar cell.

10. The solar cell group according to claim 7,
wherein the solar cells are arranged in a grid pattern, and
wherein a shortest distance between adjacent solar cells is 5 mm or less.

11. The solar cell group according to claim 7,
wherein the solar cell is a solar cell module including the plurality of solar cells sandwiched between two sealing members, and
wherein the sealing member on the light receiving surface side has translucency, the antireflection material being interposed between the sealing member and the solar cell.

12. A method for manufacturing a solar cell group including a plurality of solar cells arranged planarly, the method comprising the steps of:
a) forming the solar cells;
b) measuring color elements of the solar cells;
c) transmitting a measurement result in step b) to an arrangement determination device;
d) determining an arrangement of the solar cells constituting the solar cell group based on the measurement result received by the arrangement determination device; and
e) arranging the solar cells based on a determination of the arrangement determination device in step d).

13. The method according to claim 12,
wherein step d) determines the arrangement of the solar cells in consideration of the measurement result such that each solar cell has a good color balance,
the arrangement being determined based on past measurement results in color elements of each of the solar cells in the solar cell group and past determination results whether to have a good color balance between each of the solar cells in the solar cell group.

14. The method according to claim 12,
wherein the solar cell includes an identification part,
wherein the method includes:
f) associating the identification part of the solar cell with the measurement result; and
g) accommodating the solar cell associated with the measurement result in step f) into an accommodating member, and
wherein in step e), the solar cell associated with the measurement result in step f) is taken out from the accommodating member and is arranged based on the determination result of the arrangement determination device in step d).

15. The method according to claim 12,
wherein step b) measures the color elements of the solar cell at a plurality of measurement points, and
wherein step d) determines the arrangement of the solar cells using an average value of the color elements measured at the plurality of measurement points.
